(19) United States
(12) Patent Application Publication
(10) Pub. No.: US 2024/0161951 A1
(43) Pub. Date: May 16, 2024

(54) PROGRAMMABLE MATERIAL

(71) Applicant: Dario Maximilian Spera, Roma (IT)

(72) Inventor: Dario Maximilian Spera, Roma (IT)

(21) Appl. No.: 18/281,302

(22) PCT Filed: Mar. 3, 2022
(86) PCT No.: PCT/IT2022/050043

§ 371 Date: Sep. 10, 2023

(30) Foreign Application Priority Data
Mar. 11, 2021 (IT) 102021000005720

(51) Int. Cl. H01F 1/01; C09K 11/02; B82Y 20/00; B82Y 25/00

(52) U.S. Cl. CPC H01F 1/01; C09K 11/02; B82Y 20/00; B82Y 25/00

(57) ABSTRACT

Material programmable through energetic stimuli, comprising quantum-dots.

Said material rapidly reacts to ionic, photonic, mechanical, electrical, magnetic and thermal stimuli, so as to assume the physical features required for the application for which it is to be used.

### FIELD OF THE INVENTION

The present invention relates to the field of smart materials, which change their properties as a function of external stimuli, adapting to the applications for which they are used. In particular, the present invention relates to a material programmable by means of energetic stimuli and comprising quantum-dots; said material having a retentive character, i.e., capable of maintaining the orientation and/or the quantum state of the charges therein over time.

Said material, used for example to induce electromagnetic activities with desired properties, through surfaces or through the epidermis so as to achieve restorative or curative effects.

Said material is suitable to interact with biological, metabolic, chemical and physical effects.

### STATE OF THE ART

Materials engineering has currently made great strides, exploring the frontiers of nano and micro technologies.

For example, what are called smart materials, such as piezoelectrics, magnetostrictives, shape memory polymers, shape memory alloys, ferrofluids, photomechanics.

Another avant-garde category are composite materials, in which an attempt is made to enclose the mechanical performance excellence with specific properties of the material: chemical, electromagnetic, medical properties, etc. One specific category is for example materials which have the ability to monitor or self-repair their structure (e.g., Intrinsic Self Sensing Concrete), which are increasingly popular in civil engineering.

Disadvantageously, each of these materials is carefully designed for a specific application and this makes the production of these materials very expensive because they have narrow application fields which do not justify investment in large-scale production. A single application corresponds to a structure, with no possibility of adapting the material to different applications without changing the hardware thereof.

Disadvantageously, said materials require laborious, complex and costly processing in order to have particular properties.

The need is therefore felt to create a material which allows the aforesaid drawbacks to be overcome.

### DETAILED DESCRIPTION OF THE INVENTION

The primary object of the present invention is to create a material programmable through energetic stimuli, which changes its physical and chemical properties according to the application for which it is intended.

Advantageously, said programmable material can also be stimulated by simple actions such as rubbing, movement, exposure to sunlight, heat, electric and magnetic fields.

For example, if it were inserted in a wearable device, it could react to body heat, producing electromagnetic fields with curative effects for the individual.

Another example could be the application of a label made of the material object of the invention, placed on food products. Said material, stimulated during manufacture, so as to orient the electrical charges of the food product to reduce or induce the oxidation thereof and prolong the shelf life thereof.

Therefore, the present invention proposes to achieve the above-discussed objects by creating, according to a preferred embodiment, a material programmable by means of energetic stimuli which, in accordance with claim 1, comprises quantum-dots; said material having a retentive character, i.e., suitable to maintain the orientation and/or the quantum state of the charges comprised in said quantum-dots over time.

Optionally, said material can further comprise electrical, ionic, electronic, photonic charges and/or combinations thereof.

Programmable means that by energetically stimulating the material object of the invention, the material is capable of abruptly orienting all or a portion of the charges of which it is composed.

Optionally, the charges of which the material is composed can assume different orientations as a function of the intended application.

Alternatively, or in combination with the orientation of the charges, they also assume the same quantum state, so as to give the material a well-defined energetic expression which gives it the physical features needed for a desired application.

Advantageously, its programmability makes the material extremely adaptable and therefore usable in countless applications based on the orientation and/or quantum state of the charges comprised therein.

Advantageously, the retentive character of the programmable material makes it reliable and durable. The ability to express the energetic activity for which the material is programmed is ensured by the presence of quantum dots, which by virtue of their structure allow the charges contained therein and programmed with a defined orientation and quantum state to express themselves energetically whenever they are excited and to perform the function for which they have been programmed.

Preferably, the quantum-dots used are among quantum-dots of graphene, yttrium, InGaAs in GaAs, CdSe in ZnS, PbSin CdS.

Optionally, the quantum-dots are chemically functionalized with an R-group; said R-group is among: —H, —OH, —C, alkanes, cyclo-alkanes, aromatics, ketones, esters, ethers or any element of the periodic table with a valence suitable for quantum-dot bond formation and combinations thereof.

The functionalization of the quantum-dots makes it possible to extend the fields of application of the programmable material, as a function of the energy level and/or quantum state of the charges in the functional group. Thereby, the adaptability of the material is ideally infinite. Optionally, the programmable material further comprises carbonaceous material and/or piezoelectric material and/or pyroelectric material and/or ionic powder and/or ionic liquid.

The carbonaceous material for example between 30%-40% by weight.

The piezoelectric and/or pyroelectric material, preferably tourmaline powder, is between 30% and 40% by weight.

For example, the carbonaceous material consists of carbon nanotubes (CNTs).

The ionic powder, preferably Al and/or Mg powder, is between 20% and 40% by weight.

Optionally, the programmable material comprises magnetostrictive powder, e.g., Terfenol-D and/or Garfenol.

Optionally, the programmable metal comprises up-converting-nanocrystals (UCN).

Advantageously, the UCNs are excited by many low-energy units, e.g., photons in the infrared, and emit fewer but more energetic units.

Optionally, the programmable material comprises fluorescent and/or phosphorescent and/or fluoro-phosphorescent material.

The dependent claims describe preferred embodiments of the invention.

The present invention has been described by way of non-limiting illustration, in accordance with its preferred forms of embodiment, but it is to be understood that variations and/or modifications may be made by those skilled in the art without departing from the relevant scope of protection as defined by the appended claims.

1-4. (canceled)

5. Material programmable by means of energetic stimuli characterized in that it has a retentive character, i.e., capable of maintaining at least one of the orientation and the quantum state of the charges comprised within quantum-dots and up-converting-nanocrystals over time; said programmable material further comprising:
a magnetostrictive powder
a carbonaceous material between 30%-40% by weight;
an ionic powder between 30%-40% by weigh;
at least one of piezoelectric and pyroelectric material between 20%-40% by weight.

6. Programmable material according to claim 5, wherein the at least one of piezoelectric and pyroelectric material is at least one of tourmaline powder, barium titanate, and quartz powder.

7. Programmable material according to claim 6, wherein the in ionic powder includes at least one of Mg powder, Al powder, Ag powder and combinations thereof.

8. Programmable material according to claim 5, wherein the in ionic powder includes at least one of Mg powder, Al powder, Ag powder and combinations thereof.

9. Programmable material according to claim 5, wherein the magnetostrictive powder is at least one of Terfenol-D and Garfenol.

10. Programmable material according to claim 6, wherein the magnetostrictive powder is at least one of Terfenol-D and Garfenol.

11. Programmable material according to claim 7, wherein the magnetostrictive powder is at least one of Terfenol-D and Garfenol.

12. Programmable material according to claim 8, wherein the magnetostrictive powder is at least one of Terfenol-D and Garfenol.
